(19) United States
(12) Patent Application Publication
(10) Pub. No.: US 2025/0324871 A1
(43) Pub. Date: Oct. 16, 2025

(54) DISPLAY DEVICE AND ELECTRONIC INCLUDING THE SAME

(71) Applicant: SAMSUNG DISPLAY CO., LTD., YONGIN-SI (KR)

(72) Inventors: TAE HYUN KIM, Yongin-si (KR); SUNYOUNG JUNG, Yongin-si (KR); JOOHEE JEON, Yongin-si (KR)

(21) Appl. No.: 19/009,542

(22) Filed: Jan. 3, 2025

(30) Foreign Application Priority Data
Apr. 16, 2024 (KR) 10-2024-0050767

(51) Int. Cl. H10K 59/131

(52) U.S. Cl. CPC H10K 59/131

(57) ABSTRACT

A display device includes: a substrate including a display area and a peripheral area, a light emitting element disposed in the display area and including an anode electrode, a light emitting layer disposed on the anode electrode, and a cathode electrode disposed on the light emitting layer and extending from the display area to the peripheral area, a common voltage supply line disposed in the peripheral area, electrically connected to the cathode electrode, and including: a first metal line, a second metal line disposed on the first metal line, a third metal line disposed on the second metal line, and a connection pattern including a same material as the anode electrode and contacting the third metal line and the cathode electrode, and a transmission line disposed in the peripheral area, including a same material as the third metal line, and connected to the common voltage supply line.

### CROSS-REFERENCE TO RELATED APPLICATION

This application claims priority under 35 U.S.C. § 119 to Korean Patent Application No. 10-2024-0050767, filed on Apr. 16, 2024, in the Korean Intellectual Property Office (KIPO), the entire contents of which are hereby incorporated by reference.

### BACKGROUND

### 1. Technical Field

The present application is related to a display device. More particularly, the present application is related to a display device that provides visual information.

### 2. Discussion of Related Art

As information technology continues to develop, the importance of display devices is increasing. The display devices may be a means for communicating information to users. Accordingly, the use of display devices such as a liquid crystal display device, an organic light emitting display device, a plasma display device, and the like is increasing.

### SUMMARY

Embodiments provide a display device with reduced power consumption and improved mura phenomenon.

A display device according to embodiments of the present invention includes a substrate including a display area and a peripheral area disposed at a side of the display area, a light emitting element disposed in the display area and including an anode electrode, a light emitting layer disposed on the anode electrode, and a cathode electrode disposed on the light emitting layer and extending from the display area to the peripheral area, a common voltage supply line disposed in the peripheral area, electrically connected to the cathode electrode, and including: a first metal line, a second metal line disposed on the first metal line and contacting the first metal line, a third metal line disposed on the second metal line and contacting the second metal line, and a connection pattern including a same material as the anode electrode and contacting the third metal line and the cathode electrode, and a transmission line disposed in the peripheral area, including a same material as the third metal line, and connected to the common voltage supply line through the connection pattern.

In an embodiment, the display device may further include a gate driver disposed in the peripheral area and including at least on driver transistor and a control signal line disposed in the peripheral area, electrically connected to the gate driver, the third metal line, and the transmission line. The connection pattern may overlap the control signal line in a plan view and may be spaced apart from the control signal line.

In an embodiment, the display device may further include a first organic insulating layer disposed on the substrate and extending from the display area to the peripheral area to cover an end portion of the first metal line, a second organic insulating layer disposed on the second organic insulating layer and extending from the display area to the peripheral area to cover an end portion of the second metal line, and a third organic insulating layer disposed on the second organic insulating layer and extending from the display area to the peripheral area to cover an end portion of the third metal line.

In an embodiment, an opening may be defined in the third organic insulating layer to expose at least a portion of the transmission line, and the connection pattern may contact the transmission line through the opening.

In an embodiment, the transmission line may be directly connected to an end portion of the common voltage supply line adjacent to a pad area of the peripheral area.

In an embodiment, a plurality of through holes exposing at least a portion of the third organic insulating layer may be defined in the connection pattern.

In an embodiment, the cathode electrode may extend from the display area to a position overlapping an end portion of the third organic insulating layer contacting the third metal line.

In an embodiment, the display device may further include a first voltage line disposed in the display area and extending in a first direction and a second voltage line disposed in the display area, disposed in a different one of the first organic insulating layer, the second organic insulating layer, or the third organic insulating layer from the first voltage line, and extending in a second direction crossing the first direction.

In an embodiment, the transmission line may be connected to the first voltage line through a first contact hole penetrating the first organic insulating layer and second organic insulating layer, and the transmission line may be connected to the second voltage line through a second contact hole penetrating the first organic insulating layer.

In an embodiment, in an area adjacent to an edge portion of the display area adjacent to a pad area of the peripheral area, the first voltage line may be divided into a first part connected to the second voltage line, a second part spaced apart from the first part in a direction opposite to the first direction and connected to a first transmission line portion of the transmission line, and a third part spaced apart from the first part in the first direction and connected to a second transmission line portion of the transmission line.

In an embodiment, the display device may further include a common voltage line disposed in the display area, electrically connected to the common voltage supply line, and having a mesh structure.

In an embodiment, the common voltage line may be directly connected to an end portion of the common voltage supply line adjacent to a pad area of the peripheral area.

In an embodiment, the display device may further include a data line extending in the second direction. The anode electrode at least partially may overlap the data line in a plan view. The common voltage line may include a first common voltage line overlapping the first voltage line in a plan view and extending in the first direction and a second common voltage line covering a portion of the data line overlapping the anode electrode and extending in the second direction.

In an embodiment, the first common voltage line may cover at least one disconnected portion of at least one of the first voltage line or the second voltage line.

A display device according to embodiments of the present invention includes a substrate including a display area and a peripheral area surrounding at least a portion of the display area, a light emitting element disposed in the display area and including an anode electrode, a light emitting layer disposed on the anode electrode, and a cathode electrode disposed on the light emitting layer and extending from the display area to the peripheral area, a common voltage supply line comprising a plurality of metal layers sequentially stacked and disposed in the peripheral area, and contacting the cathode electrode, a first voltage line disposed in the display area and extending in a first direction, a second voltage line disposed in the display area, disposed in a different layer from the first voltage line, extending in a second direction crossing the first direction, and a common voltage line disposed in the display area, electrically connected to the common voltage supply line, and having a mesh structure.

In an embodiment, the display device may further include a first organic insulating layer disposed on the substrate and extending from the display area to the peripheral area, a second organic insulating layer disposed on the second organic insulating layer and extending from the display area to the peripheral area, and a third organic insulating layer disposed on the second organic insulating layer and extending from the display area to the peripheral area. The common voltage line may be disposed between the second organic insulating layer and the third organic insulating layer.

In an embodiment, the common voltage line may be directly connected to an end portion of the common voltage supply line adjacent to a pad area of the peripheral area.

In an embodiment, the display device may further include a data line extending in the second direction. The anode electrode at least partially may overlap the data line in a plan view, and the common voltage line may include a first common voltage line covering a disconnected portion of the first voltage line in a plan view and extending in the first direction and a second common voltage line covering a portion of the data line overlapping the anode electrode and extending in the second direction.

In an embodiment, a mesh structure may be formed in a portion of the display area comprising the first voltage line and the second voltage line.

In an embodiment, at least a portion of the common voltage line covers a portion of the first voltage line and at least a portion of the anode electrode covers a portion of the second voltage line.

An electronic device according to embodiments of the present disclosure includes a display device and a processor which controls the display device. The display device includes: a substrate including a display area and a peripheral area disposed at a side of the display area, a light emitting element disposed in the display area and including an anode electrode, a light emitting layer disposed on the anode electrode, and a cathode electrode disposed on the light emitting layer and extending from the display area to the peripheral area, a common voltage supply line disposed in the peripheral area, electrically connected to the cathode electrode, and including: a first metal line, a second metal line disposed on the first metal line and contacting the first metal line, a third metal line disposed on the second metal line and contacting the second metal line, and a connection pattern including a same material as the anode electrode and contacting the third metal line and the cathode electrode, and a transmission line disposed in the peripheral area, including a same material as the third metal line, and connected to the common voltage supply line through the connection pattern.

A display device according to embodiments of the present disclosure may include a common voltage supply line disposed in a peripheral area, that may provide a common voltage, and including a first metal line, a second metal line, a third metal line, and a connection pattern stacked sequentially, a transmission line disposed in the peripheral area, including a same material as the third metal line, and connected to a common voltage supply line through the connection pattern, and a common voltage line disposed in a display area, formed integrally with the transmission line, and having a mesh structure throughout the display area. Accordingly, a voltage drop (IR drop) of the common voltage may be minimized or reduced. In this case, a power consumption of the display device may be improved.

In addition, the common voltage line may include a first common voltage line extending in a first direction and a second common voltage line extending in a second direction, and the second common voltage line may cover (or shield) a portion of a data line overlapping an anode electrode. In addition, the first common voltage line may cover (or shield) a first disconnected portion of the first voltage line, and the second common voltage line may cover (or shield) a second disconnected portion of the second voltage line. Accordingly, coupling between the data line and the anode electrode may be inhibited or prevented, and the first and second disconnected portions may not be visible.

### BRIEF DESCRIPTION OF THE DRAWINGS

Illustrative, non-limiting embodiments will be more clearly understood from the following detailed description in conjunction with the accompanying drawings.

FIG. 1 is a plan view showing a display device according to embodiments of the present disclosure.

FIG. 2 is a circuit diagram showing a circuit structure of a pixel of FIG. 1.

FIG. 3 is a cross-sectional view showing a portion of a display area of FIG. 1.

FIG. 4 is an enlarged plan view of area A of FIG. 1.

FIG. 5 is a cross-sectional view taken along line I-I′ of FIG. 4.

FIG. 6 is an enlarged plan view of area B of FIG. 1.

FIG. 7 is a cross-sectional view taken along line II-II′ of FIG. 5.

FIG. 8 is a plan view showing an embodiment of a first voltage line and a second voltage line of FIG. 1.

FIG. 9 is a plan view showing an embodiment of a common voltage line of FIG. 1.

FIG. 10 is a plan view showing an embodiment of a first voltage line and a second voltage line of FIG. 1.

FIG. 11 is a plan view showing an embodiment of area C of FIG. 1.

FIG. 12, FIG. 13, FIG. 14, and FIG. 15 are cross-sectional views showing embodiments of cross-sections taken along line III-III′ of FIG. 11.

FIG. 16 is a plan view showing an embodiment of area C of FIG. 1.

FIG. 17 is a plan view showing an embodiment of area C of FIG. 1.

FIG. 18 is a block diagram illustrating an electronic device according to an embodiment of the present disclosure.

### DETAILED DESCRIPTION

Hereinafter, a display device according to embodiments of the present disclosure will be explained in detail with reference to the accompanying drawings. Inventive concepts may be implemented in various modifications and have various forms. It is to be understood, however, that the inventive concepts are not intended to be limited to the particular forms disclosed, but on the contrary, is intended to cover all modifications, equivalents, and alternatives falling within the spirit and scope of the inventive concepts. The same reference numerals are used for the same components in the drawings, and redundant descriptions of the same components may be omitted or simplified. In the drawings, the thicknesses, the ratios, and the dimensions of the elements may be exaggerated for the effective description of the technical contents.

In this specification, a plane may be defined as a first direction DR1 and a second direction DR2 crossing the first direction DR1. For example, the first direction DR1 may be perpendicular to the second direction DR2. In addition, a third direction DR3 may be perpendicular to the plane.

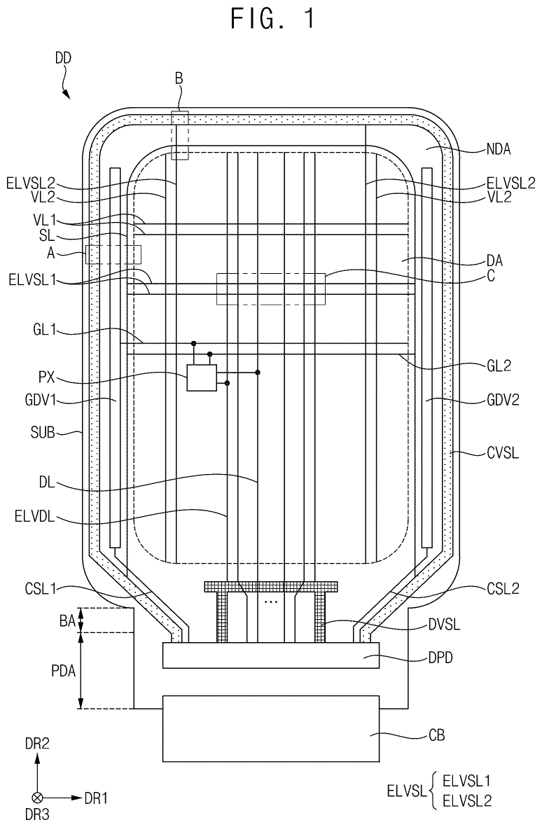

FIG. 1 is a plan view showing a display device according to embodiments of the present disclosure.

Referring to FIG. 1, the display device DD according to embodiments of the present disclosure may include a plurality of pixels PX, a display panel driver DPD, a circuit board CB, first and second gate drivers GDV1 and GDV2, first and second gate signal lines GL1 and GL2, a common voltage supply line CVSL, a driving voltage supply line DVSL, a data line DL, a driving voltage line ELVDL, a common voltage line ELVSL, a transmission line SL, first and second voltage lines VL1 and VL2, and first and second control signal lines CSL1 and CSL2 disposed on a substrate SUB.

The display device DD may include a display area DA and a peripheral area NDA. The display area DA may be an area that can display an image by generating light or adjusting the transmittance of light provided from an external light source. The peripheral area NDA may be an area that does not display images. The peripheral area NDA may be disposed on a side of the display area DA. The peripheral area NDA may surround at least a portion of the display area DA. For example, the peripheral area NDA may entirely surround the display area DA.

As the display device DD includes the display area DA and the peripheral area NDA, components included in the display device DD (e.g., the substrate SUB and the like) may be disposed in the display area DA and/or the peripheral area NDA.

The peripheral area NDA may include a bending area BA and a pad area PDA. The bending area BA may be located between the display area DA and the pad area PDA in the plan view. The bending area BA may be bent at a bending axis extending in the first direction DR1. In addition, the pad area PDA may have a shape extending along a side of the display device DD. For example, the pad area PDA may have a shape extending along the first direction DR1.

The plurality of pixels PX may be arranged in the display area DA. Each of the pixels PX may include a driving transistor that may generate a driving current and a light emitting element that may be electrically connected to the driving transistor and that may generate light based on the driving current. Accordingly, the pixels PX may generate light according to the driving current. The pixels PX may be entirely arranged in the display area DA in a matrix form along the first direction DR1 and the second direction DR2.

Drivers for driving the pixels PX may be disposed in the peripheral area NDA. For example, the first gate driver GDV1, the second gate driver GDV2, and the display panel driver DPD may be disposed in the peripheral area NDA.

In an embodiment, the light emitting element may also be disposed in a portion of the peripheral area NDA adjacent to an edge portion of the display area DA. In this case, the driving transistor that generates the driving current may not be disposed in the peripheral area NDA.

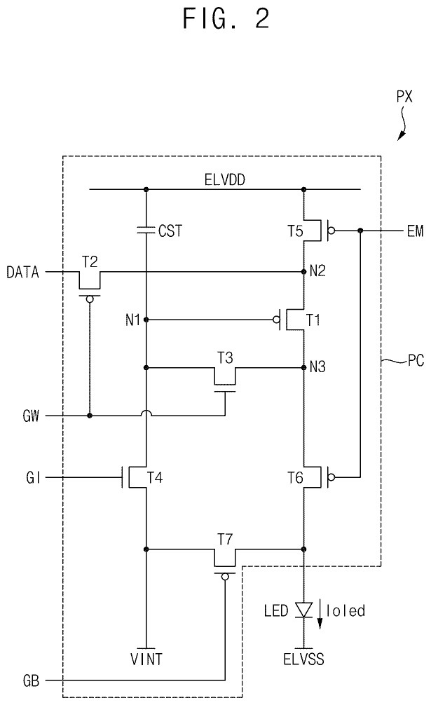

For example, the first gate driver GDV1 may be disposed in the peripheral area NDA adjacent to a left edge portion of the display area DA. The first gate driver GDV1 may include at least one driver transistor. The first gate driver GDV1 may receive a first control signal from the display panel driver DPD and generate a first gate signal based on the first control signal. For example, the first gate signal may be at least one of gate signals GW, GI, or GB, or light emitting control signal EM of FIG. 2. For example, the first gate signal may be at least one of the gate signal GW, the gate signal GI, the gate signal GB, or the light emitting control signal EM.

For example, the second gate driver GDV2 may be disposed in the peripheral area NDA adjacent to a right edge portion of the display area DA. The second gate driver GDV2 may include at least one driver transistor. The second gate driver GDV2 may receive a second control signal from the display panel driver DPD and generate a second gate signal based on the second control signal. For example, the second gate signal may be at least one of the gate signals GW, GI, or GB, or the light emitting control signal EM of FIG. 2. For example, the second gate signal may be at least one of the gate signal GW, the gate signal GI, the gate signal GB, or the light emitting control signal EM.

At least a portion of the data line DL, the first gate signal line GL1, the second gate signal line GL2, and the driving voltage line ELVDL connected to the pixels PX may be disposed in the display area DA. In an embodiment, portions of the common voltage line ELVSL, the first voltage line VL1, and the second voltage line VL2 may be further disposed in the display area DA.

In addition, at least a portion of the first control signal line CSL1 connected to the first gate driver GDV1, the second control signal line CSL2 connected to the second gate driver GDV2, the driving voltage supply line DVSL connected to the display panel driver DPD, the common voltage supply line CVSL connected to the display panel driver DPD, and the transmission line SL connected to the common voltage supply line CVSL may be disposed in the peripheral area NDA.

The first gate signal line GL1 may be electrically connected to the first gate driver GDV1 and may extend in the first direction DR1. The first gate signal line GL1 may receive the first gate signal from the first gate driver GDV1 and may provide the first gate signal to the pixels PX.

The second gate signal line GL2 may be electrically connected to the second gate driver GDV2 and may extend in the first direction DR1. The second gate signal line GL2 may receive the second gate signal from the second gate driver GDV2 and may provide the second gate signal to the pixel PX.

The data line DL may be electrically connected to the display panel driver DPD and may extend in the second direction DR2. The data line DL may receive a data voltage from the display panel driver DPD. The data voltage may be a data voltage DATA of FIG. 2. The data line DL may provide the data voltage to the pixels PX.

The driving voltage supply line DVSL may be disposed between the display panel driver DPD and the display area DA in the plan view. The driving voltage supply line DVSL may be electrically connected to the driving voltage line ELVDL. The driving voltage supply line DVSL may receive a driving voltage from the display panel driver DPD and may provide the driving voltage to the driving voltage line ELVDL. The driving voltage may be a driving voltage ELVDD of FIG. 2.

The driving voltage line ELVDL may extend along the second direction DR2. The driving voltage line ELVDL may provide the driving voltage to the pixels PX.

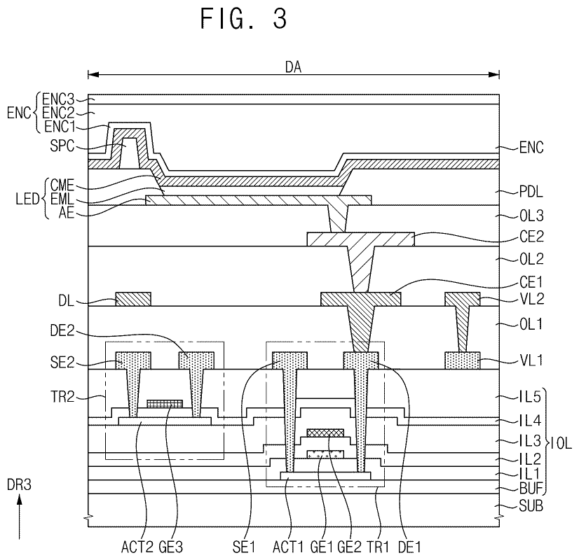

The common voltage supply line CVSL may extend along an edge portion of the peripheral area NDA. That is, the common voltage supply line CVSL may be disposed to surround at least a portion of the display area DA. Specifically, the common voltage supply line CVSL may include a first portion extending in the second direction DR2 and disposed at a left edge portion of the peripheral area NDA, a second portion extending from the first part in the first direction DR1 and disposed at an upper edge portion of the peripheral area NDA, and a third portion extending from the second part in the second direction DR2 and disposed at a right edge portion of the peripheral area NDA. The common voltage supply line CVSL may receive a common voltage from the display panel driver DPD and may provide the common voltage to a cathode electrode. The common voltage may be a common voltage ELVSS of FIG. 2. The cathode electrode may be the cathode electrode CME of FIG. 3.

The transmission line SL may be connected to an end portion of the common voltage supply line CVSL adjacent to the pad area PDA. For example, the transmission line SL may be directly connected to an end portion of the common voltage supply line CVSL adjacent to the pad area PDA. The transmission line SL may extend along an edge portion of the peripheral area NDA between the display area DA and the common voltage supply line CVSL. The transmission line SL may provide the common voltage to the cathode electrode through the common voltage supply line CVSL.

The first voltage line VL1 may extend in the first direction DR1, and the second voltage line VL2 may extend in the second direction DR2. The first voltage line VL1 may be connected to the second voltage line VL2 through a contact hole.

In an embodiment, the first voltage line VL1 and the second voltage line VL2 may be connected to the transmission line SL. In this case, the common voltage may be applied to the first voltage line VL1 and the second voltage line VL2. Accordingly, the first voltage line VL1 and the second voltage line VL2 may provide the common voltage to the cathode electrode. However, embodiments of the present disclosure are not necessarily limited thereto, and the first voltage line VL1 and the second voltage line VL2 may not be connected to the transmission line SL and the common voltage supply line CVSL. In this case, a voltage other than the common voltage may be applied to the first voltage line VL1 and the second voltage line VL2. The common voltage may be an initialization voltage VINT of FIG. 2.

The common voltage line ELVSL may include a first common voltage line ELVSL1 and a second common voltage line ELVSL2. The first common voltage line ELVSL1 may extend in the first direction DR1, and the second common voltage line ELVSL2 may extend in the second direction DR2. In an embodiment, the first common voltage line ELVSL1 and the second common voltage line ELVSL2 may be formed integrally. For example, the first common voltage line ELVSL1 and the second common voltage line ELVSL2 may be formed of the same material in the same process.

In an embodiment, the first common voltage line ELVSL1 and the second common voltage line ELVSL2 may be connected to the transmission line SL. Accordingly, the first common voltage line ELVSL1 and the second common voltage line ELVSL2 may be electrically connected to the common voltage supply line CVSL. In this case, the common voltage may be applied to the first common voltage line ELVSL1 and the second common voltage line ELVSL2. Accordingly, the first common voltage line ELVSL1 and the second common voltage line ELVSL2 may provide the common voltage to the cathode electrode.

The first control signal line CSL1 may be electrically connected to the display panel driver DPD. The first control signal line CSL1 may receive the first control signal from the display panel driver DPD and may provide the first control signal to the first gate driver GDV1.

The second control signal line CSL2 may be electrically connected to the display panel driver DPD. The second control signal line CSL2 may receive the second control signal from the display panel driver DPD and may provide the second control signal to the second gate driver GDV2.

The display panel driver DPD may be disposed in the pad area PDA. The display panel driver DPD may be formed as an integrated circuit (IC). For example, when the substrate SUB of the display device DD includes glass, the display panel driver DPD may have a chip on glass (COG) structure disposed directly on the substrate SUB. In an example in which the substrate SUB includes plastic, the display panel driver DPD may have a chip on plastic (COP) structure disposed directly on the substrate SUB. However, embodiments of the present disclosure are not necessarily limited thereto.

The display panel driver DPD may generate various signals and/or voltages. For example, the display panel driver DPD may generate the first control signal, the second control signal, the driving voltage, the common voltage, and/or the data voltage.

The circuit board CB may be disposed in the pad area PDA. Specifically, the circuit board CB may partially overlap the pad area PDA. That is, a first portion of the circuit board CB may overlap the pad area PDA, and a second portion of the circuit board CB excluding the first portion may not overlap the pad area PDA. The circuit board CB may be bonded to the substrate through an adhesive layer. For example, the adhesive layer may be an anisotropic conductive film. The circuit board CB may provide various signals and/or voltages to the display panel driver DPD.

For example, the circuit board CB may include a printed circuit board (PCB), a flexible printed circuit board (FPCB), or a flexible flat cable (FFC). However, embodiments of the present disclosure are not necessarily limited thereto.

FIG. 2 is a circuit diagram showing a circuit structure of a pixel of FIG. 1.

Referring to FIG. 2, each pixel PX may include a pixel driving circuit part PC and a light emitting element LED electrically connected to the pixel driving circuit part PC. The pixel driving circuit part PC may generate a driving current Ioled, and the light emitting element LED may generate light based on the driving current Ioled.

The pixel driving circuit part PC may include a plurality of transistors and a storage capacitor Cst. For example, the pixel driving circuit part PC may include a first transistor T1, a second transistor T2, a third transistor T3, a fourth transistor T4, a fifth transistor T5, a sixth transistor T6, a seventh transistor T7, and the storage capacitor Cst.

In an embodiment, each of the first transistor T1, the second transistor T2, the fifth transistor T5, the sixth transistor T6, and the seventh transistor T7 may be a PMOS transistor each of and the third transistor T3 and the fourth transistor T4 may be an NMOS transistor. However, embodiments of the present disclosure are not necessarily limited thereto.

When the pixel driving circuit part PC includes an NMOS transistor and a PMOS transistor, an active pattern of the NMOS transistor may include an oxide semiconductor, and an active pattern of the PMOS transistor may include a silicon semiconductor. However, embodiments of the present disclosure are not necessarily limited thereto. For example, the active pattern of the NMOS transistor may include a silicon semiconductor, and the active pattern of the PMOS transistor may include an oxide semiconductor.

The first transistor T1 may include a gate electrode, a first electrode, and a second electrode. The gate electrode of the first transistor T1 may be connected to a first node N1. The first electrode of the first transistor T1 may be connected to a second node N2. The second electrode of the first transistor T1 may be connected to a third node N3. The first transistor T1 may provide the driving current Ioled to the light emitting element LED.

The second transistor T2 may include a gate electrode, a first electrode, and a second electrode. The first gate signal GW may be applied to the gate electrode of the second transistor T2. The data voltage DATA may be applied to the first electrode of the second transistor T2. The second electrode of the second transistor T2 may be connected to the second node N2.

The second transistor T2 may be turned on or turned off in response to the first gate signal GW. For example, when the first gate signal GW has an activation level, the second transistor T2 may be turned on. In this case, the second transistor T2 may provide the data voltage DATA to the second node N2. When the first gate signal GW has an inactivation level, the second transistor T2 may be turned off. In this case, the second transistor T2 may block the supply of the data voltage DATA.

The third transistor T3 may include a gate electrode, a first electrode, and a second electrode. The first gate signal GW may be applied to the gate electrode of the third transistor T3. The first electrode of the third transistor T3 may be connected to the third node N3. The second electrode of the third transistor T3 may be connected between the first node N1 and the second electrode of the fourth transistor T4.

The fourth transistor T4 may include a gate electrode, a first electrode, and a second electrode. The second gate signal GI may be applied to the gate electrode of the fourth transistor T4. The first electrode of the fourth transistor T4 may be connected to the second electrode of the third transistor T3. An initialization voltage VINT may be applied to the second electrode of the fourth transistor T4.

The fourth transistor T4 may be turned on or turned off in response to the second gate signal GI. For example, when the second gate signal GI has an activation level, the fourth transistor T4 may be turned on. In this case, the fourth transistor T4 may provide the initialization voltage VINT to the second electrode of the third transistor T3. When the second gate signal GI has an inactivation level, the fourth transistor T4 may block the supply of the initialization voltage VINT.

The fifth transistor T5 may include a gate electrode, a first electrode, and a second electrode. The light emitting control signal EM may be applied to the gate electrode of the fifth transistor T5. The driving voltage ELVDD may be applied to the first electrode of the fifth transistor T5. The second electrode of the fifth transistor T5 may be connected to the second node N2.

The sixth transistor T6 may include a gate electrode, a first electrode, and a second electrode. The light emitting control signal EM may be applied to the gate electrode of the sixth transistor T6. The first electrode of the sixth transistor T6 may be connected to the third node N3. The second electrode of the sixth transistor T6 may be connected to the second electrode of the seventh transistor T7.

The fifth transistor T5 and the sixth transistor T6 may be turned on or turned off in response to the light emitting control signal EM. For example, when the light emitting control signal EM has an activation level, the fifth transistor T5 and the sixth transistor T6 may be turned on. In this case, the fifth transistor T5 and the sixth transistor T6 may provide the driving current Ioled generated by the first transistor T1 to an anode electrode of the light emitting element LED. When the light emitting control signal EM has an inactivation level, the fifth transistor T5 and the sixth transistor T6 may block the supply of the driving current Ioled generated by the first transistor T1.

The seventh transistor T7 may include a gate electrode, a first electrode, and a second electrode. The third gate signal GB may be applied to the gate electrode of the seventh transistor T7. The initialization voltage VINT may be applied to the first electrode of the seventh transistor T7. The second electrode of the seventh transistor T7 may be connected to the second electrode of the sixth transistor T6.

The seventh transistor T7 may be turned on or turned off in response to the third gate signal GB. For example, when the third gate signal GB has an activation level, the seventh transistor T7 may be turned on. In this case, the seventh transistor T7 may provide the initialization voltage VINT to the anode electrode of the light emitting element LED. When the third gate signal GB has an inactivation level, the seventh transistor T7 may block the supply of the initialization voltage VINT.

In an embodiment, the first electrode of each of the first, second, third, fourth, fifth, sixth, and seventh transistors T1, T2, T3, T4, T5, T6, and T7 may be a source electrode, and the second electrode of each of the first, second, third, fourth, fifth, sixth, and seventh transistors T1, T2, T3, T4, T5, T6, and T7 may be a drain electrode. However, embodiments of the present disclosure are not necessarily limited thereto, and at least one first electrode of the first, second, third, fourth, fifth, sixth, and seventh transistors T1, T2, T3, T4, T5, T6, and T7 may be a drain electrode, and the second electrode of the remaining of the first, second, third, fourth, fifth, sixth, and seventh transistors T1, T2, T3, T4, T5, T6, and T7 may be source electrode.

The storage capacitor Cst may include a first electrode and a second electrode. The driving voltage ELVDD may be applied to the first electrode of the storage capacitor Cst. The second electrode of the storage capacitor Cst may be connected to the first node N1.

The light emitting element LED may include an anode electrode and a cathode electrode. The anode electrode of the light emitting element LED may be connected to the second electrode of the sixth transistor T6 and the second electrode of the seventh transistor T7. The common voltage ELVSS may be applied to the cathode electrode of the light emitting element LED. The common voltage ELVSS may have a lower voltage level than the driving voltage ELVDD.

In FIG. 2, a pixel driving circuit part PC is shown as including seven transistors and a capacitor. Embodiments of the present disclosure are not necessarily limited thereto.

FIG. 3 is a cross-sectional view showing a portion of a display area of FIG. 1. For example, FIG. 3 is a cross-sectional view showing a pixel PX, the data line DL, the first voltage line VL1, and the second voltage line VL2 of FIG. 1.

Referring to FIG. 3, the display device DD may include the substrate SUB, an inorganic insulating layer IOL, first and second transistors TR1 and TR2, first, second, and third organic insulating layers OL1, OL2, and OL3, the first voltage line VL1, the second voltage line VL2, the data line DL, first and second connection electrodes CE1 and CE2, a pixel defining layer PDL, the light emitting element LED, a spacer SPC, and an encapsulation layer ENC.

Here, the inorganic insulating layer IOL may include a buffer layer BUF, a first insulating layer IL1, a second insulating layer IL2, a third insulating layer IL3, a fourth insulating layer IL4, and a fifth insulating layer IL5. The first transistor TR1 may include a first active pattern ACT1, a first gate electrode GE1, a second gate electrode GE2, a first source electrode SE1, and a first drain electrode DE1. The second transistor TR2 may include a second active pattern ACT2, a third gate electrode GE3, a second source electrode SE2, and a second drain electrode DE2. In addition, the light emitting element LED may include an anode electrode AE, a light emitting layer EML, and a cathode electrode CME. The encapsulation layer ENC may include a first inorganic encapsulation layer ENC1, an organic encapsulation layer ENC2, and a second inorganic encapsulation layer ENC3.

The substrate SUB may form a base of the display device DD. For example, the substrate SUB may include glass, quartz, silicon, or polymer. In addition, the substrate SUB may have a single-layer structure or a multi-layer structure in which a plurality of layers including different materials that may be stacked.

The buffer layer BUF may be disposed on the substrate SUB. The buffer layer BUF may inhibit or prevent metal atoms or impurities from diffusing from the substrate SUB. For example, the buffer layer BUF may inhibit or prevent metal atoms or impurities from diffusing from the substrate SUB to the first and second transistors TR1 and TR2. For example, the buffer layer BUF may include an insulating material such as silicon oxide, silicon nitride, or silicon oxynitride. These can be used alone or in combination with each other.

The first active pattern ACT1 may be disposed on the buffer layer BUF. For example, the first active pattern ACT1 may include a metal oxide semiconductor, a silicon semiconductor, or an organic semiconductor. In an embodiment, the first active pattern ACT1 may include a silicon semiconductor such as polysilicon. The first active pattern ACT1 may include a first source region, a first drain region, and a first channel region disposed between the first source region and the first drain region. The first source region and the first drain region may have higher conductivity than the first channel region.

The first insulating layer IL1 may be disposed on the buffer layer BUF. The first insulating layer IL1 may be disposed on the first active pattern ACT1. For example, the first insulating layer IL1 may include an insulating material such as silicon oxide, silicon nitride, or silicon oxynitride. These can be used alone or in combination with each other.

The first gate electrode GE1 may be disposed on the first insulating layer IL. The first gate electrode GE1 may overlap the first channel region of the first active pattern ACT1 in a plane view. For example, the first gate electrode GE1 may include metal, alloy, conductive metal oxide, conductive metal nitride, or transparent conductive oxide. These example materials can be used alone or in combination with each other.

The second insulating layer IL2 may be disposed on the first insulating layer IL1. The second insulating layer IL2 may be disposed on the first gate electrode GE1. For example, the second insulating layer IL2 may include an insulating material such as silicon oxide, silicon nitride, or silicon oxynitride. These example materials can be used alone or in combination with each other.

The second gate electrode GE2 may be disposed on the second insulating layer IL2. The second gate electrode GE2 may overlap the first gate electrode GE1 on a plane. For example, the second gate electrode GE2 may include metal, alloy, conductive metal oxide, conductive metal nitride, or transparent conductive oxide. These example materials can be used alone or in combination with each other.

The third insulating layer IL3 may be disposed on the second insulating layer IL2. The third insulating layer IL3 may be disposed on the second gate electrode GE2. For example, the third insulating layer IL3 may include an insulating material such as silicon oxide, silicon nitride, or silicon oxynitride. These example materials can be used alone or in combination with each other.

The second active pattern ACT2 may be disposed on the third insulating layer IL3. For example, the second active pattern ACT2 may include a metal oxide semiconductor, a silicon semiconductor, or an organic semiconductor. In an embodiment, the second active pattern ACT2 may include a metal oxide semiconductor. The second active pattern ACT2 may include a second source region, a second drain region, and a second channel region disposed between the second source region and the second drain region. The second source region and the second drain region may have higher conductivity than the second channel region.

The fourth insulating layer IL4 may be disposed on the third insulating layer IL3. The fourth insulating layer IL4 may be disposed on the second active pattern ACT2. For example, the fourth insulating layer IL4 may include an insulating material such as silicon oxide, silicon nitride, or silicon oxynitride. These example materials can be used alone or in combination with each other.

The third gate electrode GE3 may be disposed on the fourth insulating layer IL4. The third gate electrode GE3 may overlap the second channel region of the second active pattern ACT2 in a plan view. For example, the third gate electrode GE3 may include metal, alloy, conductive metal oxide, conductive metal nitride, or transparent conductive oxide. These example materials can be used alone or in combination with each other.

The fifth insulating layer IL5 may be disposed on the fourth insulating layer IL4. The fifth insulating layer IL5 may be disposed on the third gate electrode GE3. For example, the fifth insulating layer IL5 may include an insulating material such as silicon oxide, silicon nitride, or silicon oxynitride. These example materials can be used alone or in combination with each other.

The first source electrode SE1, the first drain electrode DE1, the second source electrode SE2, and the second drain electrode DE2 may be disposed on the fifth insulating layer IL5. The first source electrode SE1 may be connected to the first source region of the first active pattern ACT1 through a contact hole penetrating the inorganic insulating layer IOL excluding the buffer layer BUF, and the first drain electrode DE1 may be connected to the first drain region of the first active pattern ACT1 through a contact hole penetrating the inorganic insulating layer IOL excluding the buffer layer BUF. For example, one or more first contact holes may be defined in the first to fifth insulating layers IL1, IL2, IL3, IL4, and IL5 to expose a portion the first active pattern ACT1 disposed on the buffer layer BUF. In addition, the second source electrode SE2 may be connected to the second source region of the second active pattern ACT2 through a contact hole penetrating the fourth and fifth insulating layers IL4 and IL5, and the second drain electrode DE2 may be connected to the second drain region of the second active pattern ACT2 through a contact hole penetrating the fourth and fifth insulating layers IL4 and IL5. For example, one or more second contact holes may be defined in the fourth and fifth insulating layers IL4 and IL5 to expose a portion the second active pattern ACT2 disposed on the third insulating layer IL3.

For example, the first source electrode SE1, the first drain electrode DE1, the second source electrode SE2, and the second drain electrode DE2 may include metal, alloy, conductive metal oxide, conductive metal nitride, or transparent conductive oxide. These example materials can be used alone or in combination with each other.

The first source electrode SE1, the first drain electrode DE1, the second source electrode SE2, and the second drain electrode DE2 may include the same material and may be formed through the same process.

Accordingly, the first transistor TR1 and the second transistor TR2 may be formed in the display area DA. For example, the first transistor TR1 may correspond to the sixth transistor T6 or the seventh transistor T7 of FIG. 2, and the second transistor TR2 may correspond to the third transistor T3 or the fourth transistor T4 of FIG. 2.

The first voltage line VL1 may be disposed on the fifth insulating layer IL5. In an embodiment, the first voltage line VL1 may be disposed in the same layer as the first source electrode SE1, the first drain electrode DE1, the second source electrode SE2, and the second drain electrode DE2. That is, the first voltage line VL1 may include the same material as the first source electrode SE1, the first drain electrode DE1, the second source electrode SE2, and the second drain electrode DE2 and may be formed through the same process as the first source electrode SE1, the first drain electrode DE1, the second source electrode SE2, and the second drain electrode DE2.

As described herein, the first voltage line VL1 may be applied to the common voltage or a voltage other than the common voltage. The common voltage may be the common voltage ELVSS of FIG. 2. The common voltage may be the initialization voltage VINT of FIG. 2.

The first organic insulating layer OL1 may be disposed on the fifth insulating layer IL5. The first organic insulating layer OL1 may sufficiently cover the first source electrode SE1, the first drain electrode DE1, the second source electrode SE2, the second drain electrode DE2, and the first voltage line VL1. For example, the first organic insulating layer OL1 may include an organic material such as photoresist, polyacryl-based resin, polyimide-based resin, polyamide-based resin, siloxane-based resin, acryl-based resin, or epoxy-based resin. These example materials can be used alone or in combination with each other.

The first connection electrode CE1, the data line DL, and the second voltage line VL2 may be disposed on the first organic insulating layer OL1. The first connection electrode CE1 may be connected to the first drain electrode DE1 (or the first source electrode SE1) through a contact hole penetrating the first organic insulating layer OL1. The second voltage line VL2 may be connected to the first voltage line VL1 through a contact hole penetrating the first organic insulating layer OL1. For example, one or more fourth contact holes may be defined in the first organic insulating layer OL1.

For example, the first connection electrode CE1 may include metal, alloy, conductive metal oxide, conductive metal nitride, or transparent conductive oxide. These example materials can be used alone or in combination with each other. In addition, the first connection electrode CE1, the data line DL, and the second voltage line VL2 may include the same material and may be formed through the same process.

However, embodiments of the present disclosure are not necessarily limited thereto. For example, the first voltage line VL1 may be disposed on the first organic insulating layer OL1, and the second voltage line VL2 may be disposed on the fifth insulating layer IL5.

The second organic insulating layer OL2 may be disposed on the first organic insulating layer OL1. The second organic insulating layer OL2 may sufficiently cover the first connection electrode CE1, the data line DL, and the second voltage line VL2. For example, the second organic insulating layer OL2 may include an organic material such as photoresist, polyacrylic-based resin, polyimide-based resin, polyamide-based resin, siloxane-based resin, acrylic-based resin, or epoxy-based resin. These example materials can be used alone or in combination with each other.

The second connection electrode CE2 may be disposed on the second organic insulating layer OL2. The second connection electrode CE2 may be connected to the first connection electrode CE1 through a contact hole penetrating the second organic insulating layer OL2. For example, one or more fifth contact holes may be defined in the second connection electrode CE2. For example, the second connection electrode CE2 may include metal, alloy, conductive metal oxide, conductive metal nitride, or transparent conductive oxide. These example materials can be used alone or in combination with each other.

The third organic insulating layer OL3 may be disposed on the second organic insulating layer OL2. The third organic insulating layer OL3 may sufficiently cover the second connection electrode CE2. For example, the third organic insulating layer OL3 may include an organic material such as photoresist, polyacrylic-based resin, polyimide-based resin, polyamide-based resin, siloxane-based resin, acrylic-based resin, epoxy-based resin. These example materials can be used alone or in combination with each other.

The anode electrode AE may be disposed on the third organic insulating layer OL3. The anode electrode AE may be connected to the second connection electrode CE2 through a contact hole penetrating the third organic insulating layer OL3. For example, one or more sixth contact holes may be defined in the third organic insulating layer OL3. The anode electrode AE may be a transmissive electrode, a semi-transmissive electrode, or a reflective electrode. For example, the anode electrode AE may include a metal, alloy, conductive metal oxide, conductive metal nitride, or transparent conductive oxide. These example materials can be used alone or in combination with each other.

The pixel defining layer PDL may be disposed on the third organic insulating layer OL3. The pixel defining layer PDL may define a pixel opening that exposes at least a portion of the anode electrode AE. The pixel defining layer PDL may include inorganic materials and/or organic materials. For example, the pixel defining layer PDL may include an organic material such as epoxy resin, or siloxane resin. These example materials can be used alone or in combination with each other. In another example, the pixel defining layer PDL may include an inorganic material and/or an organic material containing a light blocking material such as black pigment, or black dye.

The spacer SPC may be disposed on the pixel defining layer PDL. The spacer SPC may serve to support a mask used in the process of forming the light emitting layer EML. The spacer SPC may be formed through a separate process from the pixel defining layer PDL. In another example, the spacer SPC may be formed simultaneously with the pixel defining layer PDL through the same process. For example, the spacer SPC may include an organic material such as polyimide.

The light emitting layer EML may be disposed on the anode electrode AE. Specifically, the light emitting layer EML may be disposed in the pixel opening of the pixel defining layer PDL. For example, the light emitting layer EML may include a light emitting material that may generate light of a specific color. For example, the light emitting layer EML may generate red light, green light, or blue light. Embodiments are not limited thereto. For example, the light emitting layer EML may generate white light.

The cathode electrode CME may be disposed on at least a portion of each of the pixel defining layer PDL, a spacer SPC, and the light emitting layer EML. The cathode electrode CME may be disposed on the entire surface of the display area DA. The cathode electrode CME may be a transmissive electrode, a transmissive electrode, or a reflective electrode. For example, the cathode electrode CME may include metal, alloy, conductive metal oxide, conductive metal nitride, or transparent conductive oxide. These example materials can be used alone or in combination with each other.

Accordingly, the light emitting element LED may be formed in the display area DA. The light emitting element LED may be electrically connected to the first transistor TR1.

The encapsulation layer ENC may be disposed on the cathode electrode CME. The encapsulation layer ENC may cover at least a portion of the light emitting element LED. The encapsulation layer ENC may include at least one inorganic encapsulation layer and at least one organic encapsulation layer. For example, as described herein, the encapsulation layer ENC may include a first inorganic encapsulation layer ENC1, a second inorganic encapsulation layer ENC3, and an organic encapsulation layer ENC2 disposed between the first inorganic encapsulation layer ENC1 and the second inorganic encapsulation layer ENC3.

For example, the first inorganic encapsulation layer ENC1 and the second inorganic encapsulation layer ENC3 may include a silicon compound, or a metal oxide. The organic encapsulation layer ENC2 may include a polymer-based material. Examples of polymer-based materials may include acrylic-based resin, epoxy-based resin, or polyimide-based resin. These example materials can be formed alone or in combination with each other.

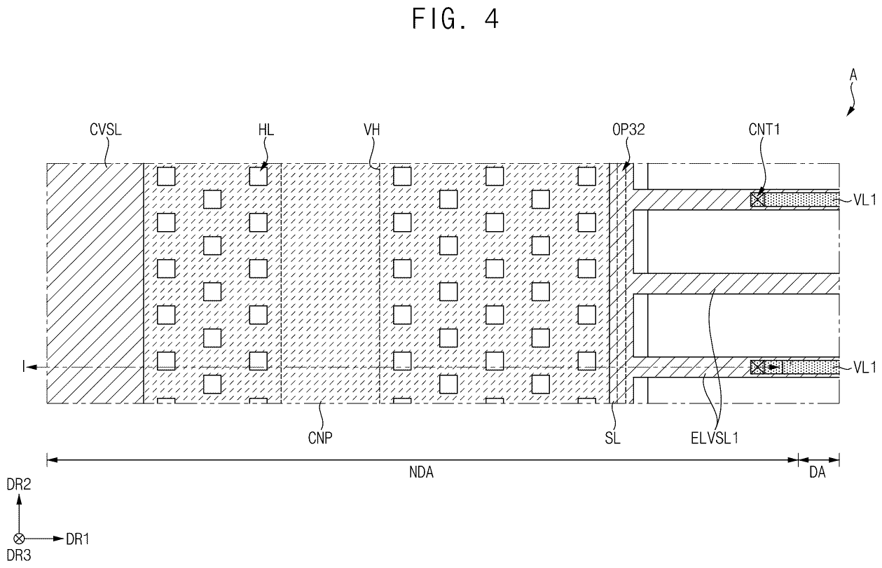

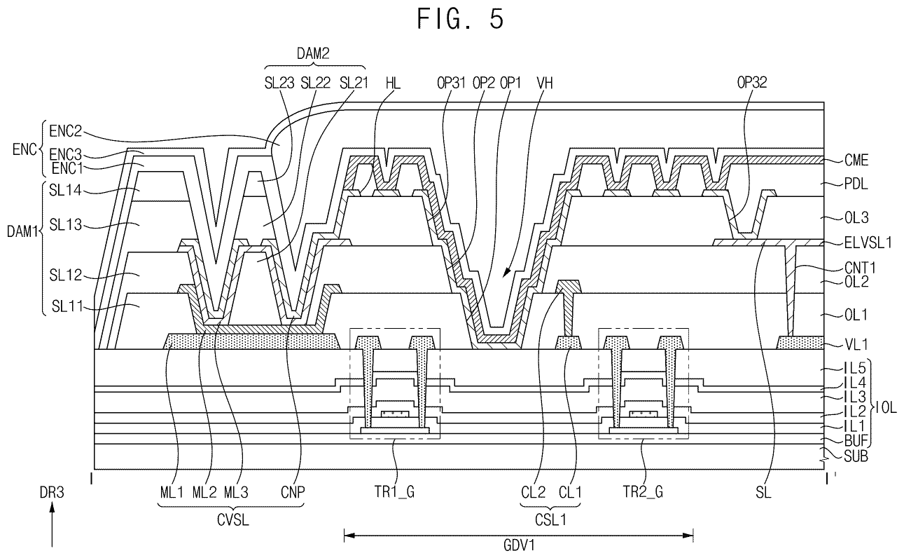

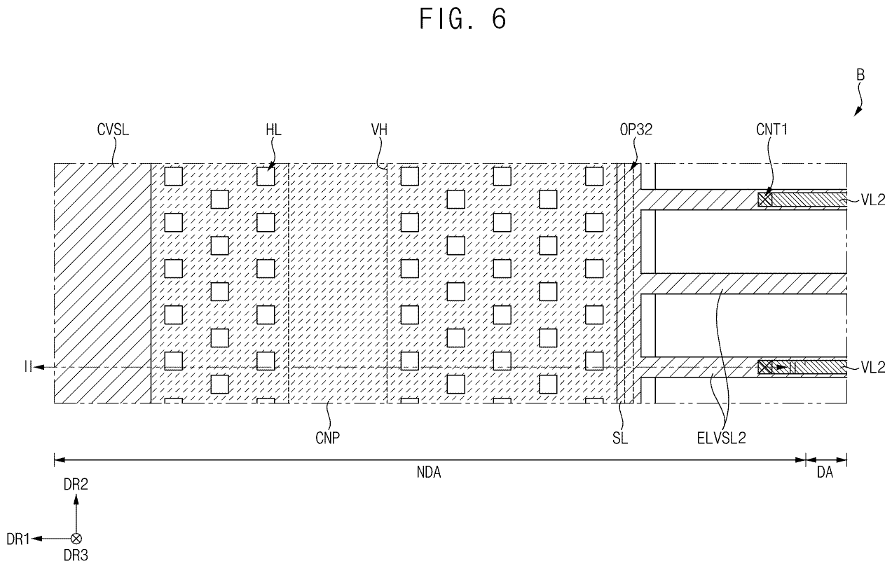

FIG. 4 is an enlarged plan view of area A of FIG. 1. FIG. 5 is a cross-sectional view taken along line I-I′ of FIG. 4. FIG. 6 is an enlarged plan view of area B of FIG. 1.

For example, FIG. 4 is an enlarged plan view showing a portion of the display area DA from the common voltage supply line CVSL disposed at the left edge portion of the peripheral area NDA. FIG. 6 is an enlarged plan view showing a portion of the display area DA from the common voltage supply line CVSL disposed at the upper edge portion of the peripheral area NDA. For convenience of illustration, only some of the metal layers constituting the common voltage supply line CVSL are shown in FIG. 4 and FIG. 6.

Hereinafter, content overlapping with the content about the display device DD described with reference to FIG. 3 may be omitted or simplified.

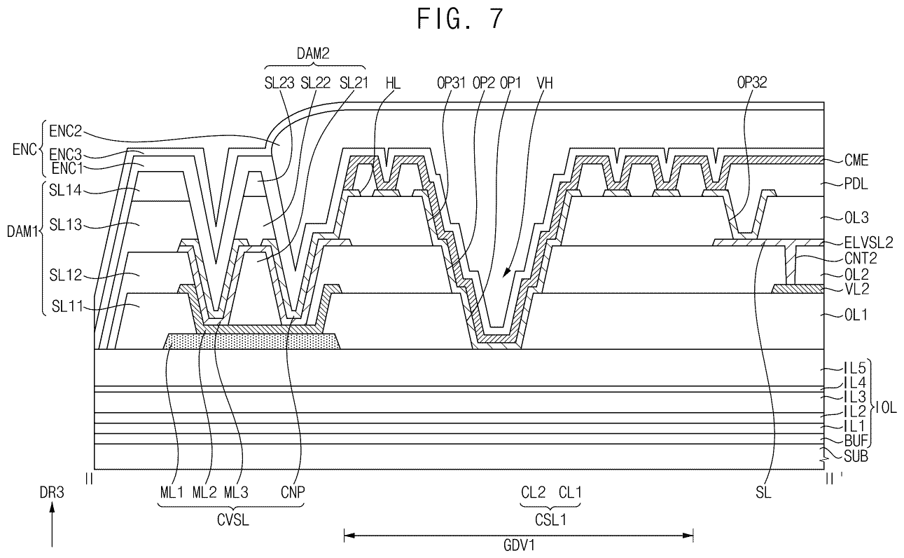

Referring to FIG. 4, FIG. 5, FIG. 6, and FIG. 7, the first gate driver GDV1 may include a first driver transistor TR1_G and a second driver transistor TR2_G. A first control signal line connected to the first gate driver GDV1 may include a first connection line CL1 and a second connection line CL2 disposed on the first connection line CL1. For example, the first connection line CL1 may be disposed in the same layer as the first source electrode SE1 and the first drain electrode DE1 of FIG. 3 and may include the same material as the first source electrode SE1 and the first drain electrode DE1 of FIG. 3, and the second connection line CL2 may be disposed in the same layer as the first connection electrode CE1 of FIG. 3 and may include the same material as the first connection electrode CE1 of FIG. 3. However, embodiments of the present disclosure are not necessarily limited thereto. The second control signal line CSL2 of FIG. 1 may also have the same stacked structure as the first control signal line CSL1.

The buffer layer BUF and the first, second, third, fourth, and fifth insulating layers IL1, IL2, IL3, IL4, and IL5 may extend from the display area DA to the peripheral area NDA. In addition, the first, second, and third organic insulating layers OL1, OL2, and OL3 and the pixel defining layer PDL may extend from the display area DA to the peripheral area NDA.

In an embodiment, in the peripheral area NDA, a first opening OP1 exposing a portion of the fifth insulating layer IL5 may be defined in the first organic insulating layer OL1, and a second opening OP2 exposing the first opening OP1 may be defined in the second organic insulating layer OL2, and a third-first opening OP31 exposing the second opening OP2 may be defined in the third organic insulating layer OL3. In addition, a third-second opening OP32 spaced apart from the third-first opening OP31 may be further defined in the third organic insulating layer OL3.

The second opening OP2 may be spatially connected to the first opening OP1, and the third-first opening OP31 may be spatially connected to the second opening OP2. Accordingly, the first opening OP1, the second opening OP2, and the third-first opening OP31 may form a valley portion VH.

The valley portion VH may be disposed to surround at least a portion of the display area DA. The valley portion VH may be disposed between the common voltage supply line CVSL and the transmission line SL in the plan view. In addition, the valley portion VH may overlap the first gate driver GDV1 in the plan view. The valley portion VH may separate the first, second, and third organic insulating layers OL1, OL2, and OL3 and the pixel defining layer PDL, thereby blocking or reducing the path through which moisture may penetrate into the display area DA from the outside of the substrate SUB through the organic layer.

The display device DD may further include a first dam DAM1 and a second dam DAM2 disposed in the peripheral area NDA. The first dam DAM1 may be closer to the edge portion of the peripheral area NDA than the second dam DAM2. In addition, the first dam DAM1 may be disposed to be spaced apart from the second dam DAM2.

The first dam DAM1 may be disposed to overlap an outer edge portion of the common voltage supply line CVSL. The first dam DAM1 may include a plurality of insulating layers. In an embodiment, the first dam DAM1 may include a first-first sub-layer SL11, a first-second sub-layer SL12, a first-third sub-layer SL13, and a first-forth sub-layer SL14 sequentially stacked on the inorganic insulating layer IOL in the third direction DR3. However, embodiments of the present disclosure are not necessarily limited thereto. For example, some of the first-first sub-layer SL11, the first-second sub-layer SL12, the first-third sub-layer SL13, and the first-forth sub-layer SL14 may be omitted.

In an embodiment, the first-first sub-layer SL11 may include the same material as the first organic insulating layer OL1 and may be formed through the same process as the first organic insulating layer OL1. The first-second sub-layer SL12 may include the same material as the second organic insulating layer OL2 and may be formed through the same process as the second organic insulating layer OL2. The first-third sub-layer SL13 may include the same material as the pixel defining layer PDL and may be formed through the same process as the pixel defining layer PDL. The first-fourth sub-layer SL14 may include the same material as the spacer SPC of FIG. 3 and may be formed through the same process as the spacer SPC of FIG. 3.

The second dam DAM2 may be disposed on the common voltage supply line CVSL. The second dam DAM2 may include a plurality of insulating layers. In an embodiment, the second dam DAM2 may include a second-first sub-layer SL21, a second-second sub-layer SL22, and a second-third sub-layer SL23 sequentially stacked on the inorganic insulating layer IOL. However, embodiments of the present disclosure are not necessarily limited thereto. For example, some of the second-first sub-layer SL21, the second-second sub-layer SL22, and the second-third sub-layer SL23 may be omitted.

In an embodiment, the second-third sub-layer SL21 may include the same material as the second organic insulating layer OL2 and may be formed through the same process as the second organic insulating layer OL2. The second-second sub-layer SL22 may include the same material as the pixel defining layer PDL and may be formed through the same process as the pixel defining layer PDL. The second-third sub-layer SL13 may include the same material as the spacer SPC of FIG. 3 and may be formed through the same process material as the spacer SPC of FIG. 3.

The common voltage supply line CVSL may include a plurality of metal layers sequentially stacked in the third direction DR3. In an embodiment, the common voltage supply line CVSL may include a first metal line ML1, a second metal line ML2, a third metal line ML3, and a connection pattern CNP sequentially stacked on the inorganic insulating layer IOL in the third direction DR3.

An end portion of the first metal line ML1 may be covered by the first-first sub-layer SL11 and the first organic insulating layer OL1. In an embodiment, the first metal line ML1 may include the same material as the first source electrode SE1 and the first drain electrode DE1 of FIG. 3 and may be formed through the same process as the first source electrode SE1 and the first drain electrode DE1 of FIG. 3.

The second metal line ML2 may contact the first metal line ML1. An end portion of the second metal line ML2 may contact an upper surface of the first-first sub-layer SL11 and an upper surface of the first organic insulating layer OL11. In addition, the end portion of the second metal line ML2 may be covered by the first-second sub-layer SL12 and the second organic insulating layer OL2. In an embodiment, the second metal line ML2 may include the same material as the first connection electrode CE1 of FIG. 3 and may be formed through the same process as the first connection electrode CE1 of FIG. 3.

The third metal line ML3 may contact the second metal line ML2. The third metal line ML3 may be disposed on the second-first sub-layer SL21, and an end portion of the third metal line ML3 may contact an upper surface of the first-second sub-layer SL12 and an upper surface of the second organic insulating layer OL2. In addition, the end portion of the third metal line ML3 may be covered by the first-third sub-layer SL3 and the third organic insulating layer OL3. In an embodiment, the third metal line ML3 may include the same material as the second connection electrode CE2 of FIG. 3 and may be formed through the same process as the second connection electrode CE2 of FIG. 3.

The connection pattern CNP may contact the third metal line ML3. In addition, the connection pattern CNP may be disposed to cover the first, second, and third metal lines ML1, ML2, and ML3, the valley portion VH, and the transmission line SL. That is, the connection pattern CNP may extend from on the first, second, and third metal lines ML1, ML2, and ML3 through the upper surface of the third organic insulating layer OL3 and the valley portion VH to on the transmission line SL. In addition, the connection pattern CNP may contact the transmission line SL through the third-second opening OP32. Accordingly, the common voltage supply line CVSL and the transmission line SL may be electrically connected through the connection pattern CNP.

In an embodiment, the connection pattern CNP may include the same material as the anode electrode AE of FIG. 3 and may be formed through the same process as the anode electrode AE of FIG. 3.

Excluding the area where the valley portion VH is disposed, a plurality of through holes HL may be defined in the connection pattern CNP. Some of the through holes HL may expose at least a portion of the third metal line ML3, and other portions may expose at least a portion of the third organic insulating layer OL3. The through holes HL may function as a path for discharging gas generated from organic layers disposed under the connection pattern CNP.

In an embodiment, the transmission line SL may be disposed on the second organic insulating layer OL2. That is, the transmission line SL may be disposed in the same layer as the second connection electrode CE2 of FIG. 3. The transmission line SL may include the same material as the second connection electrode CE2 of FIG. 3 and may be formed through the same process as the second connection electrode CE2 of FIG. 3.

In an embodiment, the connection pattern CNP may overlap a control signal line (e.g., the first control signal line CSL1 and the second control signal line CSL2 of FIG. 1) in the plan view, and may be spaced apart from the control signal line in the third direction DR3. For example, the connection pattern CNP, which may be disposed on the third metal line ML3 and the transmission line SL may be spaced apart from the control signal line. Accordingly, coupling between the control signal line and the third metal line ML3 and the transmission line SL may be inhibited or prevented.

A portion of the first voltage line VL1 may extend to the peripheral area NDA. In addition, a portion of the second voltage line VL2 may extend to the peripheral area NDA.

The first common voltage line ELVSL1 and the second common voltage line ELVSL2 may be disposed on the first and second voltage lines VL1 and VL2. In an embodiment, the first common voltage line ELVSL1 and the second common voltage line ELVSL2 may be disposed in the same layer as the second connection electrode CE2 of FIG. 3. That is, the first common voltage line ELVSL1 and the second common voltage line ELVSL2 may include the same material as the second connection electrode CE2 of FIG. 3 and may be formed through the same process as the second connection electrode CE2 of FIG. 3.

The first common voltage line ELVSL1 and the second common voltage line ELVSL2 may be formed integrally with the transmission line SL. Accordingly, the first common voltage line ELVSL1 and the second common voltage line ELVSL2 may be electrically connected to the common voltage supply line CVSL through the transmission line SL to receive the common voltage (e.g., the common voltage ELVSS of FIG. 2).

In an embodiment, the transmission line SL may be connected to the first voltage line VL1 through a first contact hole CNT1 penetrating the first and second organic insulating layers OL1 and OL2, and may be connected to the second voltage line VL2 through a second contact hole CNT2 penetrating the organic insulating layer OL2. Accordingly, the first and second voltage lines VL1 and VL2 may be electrically connected to the common voltage supply line CVSL through the transmission line SL to receive the common voltage. In another example, the first voltage line VL1 and the second voltage line VL2 may not be connected to the transmission line SL.

The cathode electrode CME may extend from the display area DA to the peripheral area NDA. Specifically, the cathode electrode CME may extend from the display area DA to a position overlapping at least a portion of the end portion of the third organic insulating layer OL3 contacting the third metal line ML3.

The cathode electrode CME may contact the connection pattern CNP of the common voltage supply line CVSL in the peripheral area NDA. Specifically, the cathode electrode CME may contact the connection pattern CNP at the portion of the pixel defining layer PDL between the through holes HL and the valley portion VH. Accordingly, the common voltage supply line CVSL may be electrically connected to the cathode electrode CME and may provide the common voltage to the cathode electrode CME.

The encapsulation layer ENC may extend from the display area DA to the peripheral area NDA. The first inorganic encapsulation layer ENC1 and the second inorganic encapsulation layer ENC3 of the encapsulation layer ENC may be disposed on an entire surface of the substrate SUB. The organic encapsulation layer ENC2 may extend from the display area DA to the second dam DAM2. In another example, the organic encapsulation layer ENC2 may extend from the display area DA to the first dam DAM1.

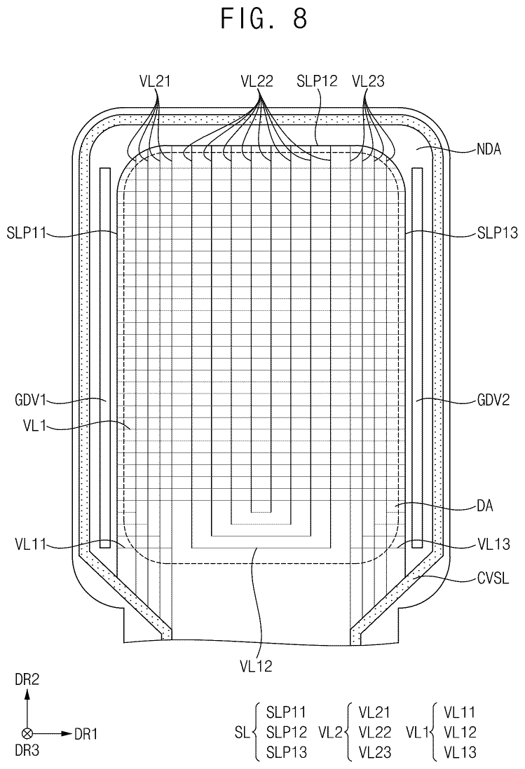

FIG. 8 is a plan view showing an embodiment of a first voltage line and a second voltage line of FIG. 1.

Referring to FIG. 8, the transmission line SL may include a first transmission line portion SLP11, a second transmission line portion SLP12, and a third transmission line portion SLP13.

The first transmission line portion SLP11 may be disposed at the left edge portion of the peripheral area NDA and may extend in the second direction DR2. The third transmission line portion SLP13 may be disposed at the right edge portion of the peripheral area NDA and may extend in the second direction DR2. The second transmission line portion SLP12 may connect the first transmission line portion SLP11 and the third transmission line portion SLP13, may be disposed at the upper edge portion of the peripheral area NDA, and extend in the first direction DR1.

In the display area DA, a plurality of first voltage lines VL1 and a plurality of second voltage lines VL2 may be provided. The plurality of first voltage lines VL1 may be disposed along the second direction DR2, and the plurality of second voltage lines VL2 may be disposed along the first direction DR1.

As described herein, in an embodiment, the first voltage line VL1 and the second voltage line VL2 may be connected to the transmission line SL. Specifically, the first voltage line VL1 may be directly connected to the first transmission line portion SLP11 and the third transmission line portion SLP13, and the second voltage line VL2 may be directly connected to the second transmission line portion SLP12. In addition, the second voltage line VL2 may be directly connected to the end portion of the common voltage supply line CVSL adjacent to the pad area (e.g., the pad area PDA of FIG. 1). Accordingly, the common voltage may be applied to the first voltage line VL1 and the second voltage line VL2.

In an embodiment, the first voltage lines VL1 and the second voltage lines VL2 may have a mesh structure in some areas of the display area DA, and may not have a mesh structure in the remaining area (i.e., an area adjacent to the pad area) of the display area DA. For example, the first voltage lines VL1 and the second voltage lines VL2 may, together, form a mesh structure in some areas of the display area DA.

In an embodiment, in an area adjacent to an edge portion of the display area DA adjacent to the pad area, the first voltage lines VL1 may be divided into a second part VL12 connected to the second voltage lines VL2, a first part VL11 spaced apart from the second part VL12 in a direction opposite to the first direction DR1 and connected to the first transmission line portion SLP11 and the second voltage lines VL2, and a third part VL13 spaced apart from the second part VL12 in the first direction DR1 and connected to the third transmission line portion SLP13 and the second voltage lines VL2.

The second voltage lines VL2 may include a first part VL21, a second part VL22, and a third part VL23. The first part VL21 of the second voltage lines VL2 may be disposed at the left edge portion of the display area DA and may be directly connected to the lower of the common voltage supply line CVSL. The third part VL23 of the second voltage lines VL2 may be disposed at the right edge portion of the display area DA and may be directly connected to the lower of the common voltage supply line CVSL. In addition, the second part VL22 of the second voltage lines VL2 may be disposed in the center of the display area DA and connected to the second part VL12 of the first voltage lines VL1.

For example, a length of the second part VL22 of the second voltage lines VL2 in the second direction DR2 may be shorter than a length of each of the first part VL21 and the third part VL21 of the second voltage lines VL2 in the second direction DR2.

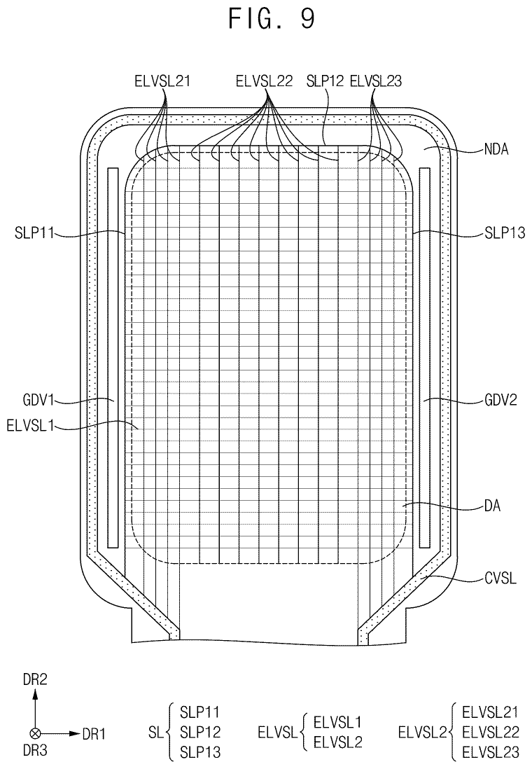

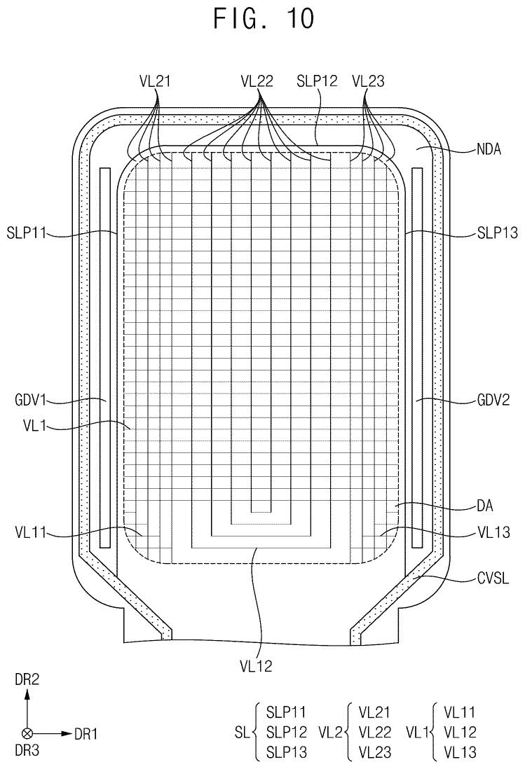

FIG. 9 is a plan view showing an embodiment of a common voltage line of FIG. 1.

Hereinafter, content overlapping with the content described with reference to FIG. 8 may be omitted or simplified.

Referring to FIG. 9, as described herein, the common voltage line ELVSL may include the first common voltage line ELVSL1 and the second common voltage line ELVSL2. The first common voltage line ELVSL1 and the second common voltage line ELVSL2 may be formed integrally with.

A plurality of first common voltage lines ELVSL1 may be provided, and a plurality of second common voltage lines ELVSL2 may be provided. The plurality of first common voltage lines ELVSL1 may be arranged along the second direction DR2, and the plurality of second common voltage lines ELVSL2 may be arranged along the first direction DR1.

As described herein, the first common voltage lines ELVSL1 and the second common voltage lines ELVSL2 may be formed integrally with the transmission line SL. Specifically, the first common voltage lines ELVSL1 may be directly connected to the first transmission line portion SLP11 and the third transmission line portion SLP13, and the second common voltage lines ELVSL2 may be connected to the second transmission line portion SLP12. In addition, the second common voltage lines ELVSL2 may be directly connected to the lower of the common voltage supply line CVSL adjacent to the pad area. Accordingly, the common voltage may be applied to the first common voltage lines ELVSL1 and the second common voltage lines ELVSL2.

In an embodiment, the first common voltage lines ELVSL1 and the second common voltage lines ELVSL2 may have a mesh structure throughout the display area DA.

The second common voltage lines ELVSL2 may include a first part ELVSL21, a second part ELVSL22, and a third part ELVSL23. The first part ELVSL21 of the second common voltage lines ELVSL2 may be disposed at the left edge portion of the display area DA and may be directly connected to the lower of the common voltage supply line CVSL. The third part ELVSL23 of the second common voltage lines ELVSL2 may be disposed at the right edge portion of the display area DA and may be directly connected to the lower of the common voltage supply line CVSL. In addition, the second part ELVSL2 of the second common voltage lines ELVSL2 may be disposed at the center of the display area DA.

For example, a length of the second part ELVSL2 of the second common voltage lines ELVSL2 in the second direction DR2 may be shorter than a length of each of the first part ELVSL21 and the third portion ELVSL23 of the second common voltage lines ELVSL2 in the second direction DR2.

FIG. 10 is a plan view showing an embodiment of a first voltage line and a second voltage line of FIG. 1.

Hereinafter, content overlapping with the content described with reference to FIG. 8 may be omitted or simplified.

Referring to FIG. 10, in an embodiment, the first voltage line VL1 and the second voltage line VL2 may not be connected to the transmission line SL and the common voltage supply line CVSL. In this case, a voltage other than the common voltage may be applied to the first voltage line VL1 and the second voltage line VL2.

The arrangement of the first voltage line VL1 and the second voltage line VL2 in the display area DA of FIG. 10 may be substantially the same as the arrangement of the first voltage line VL1 and the second voltage line VL2 in the display area DA of FIG. 8.

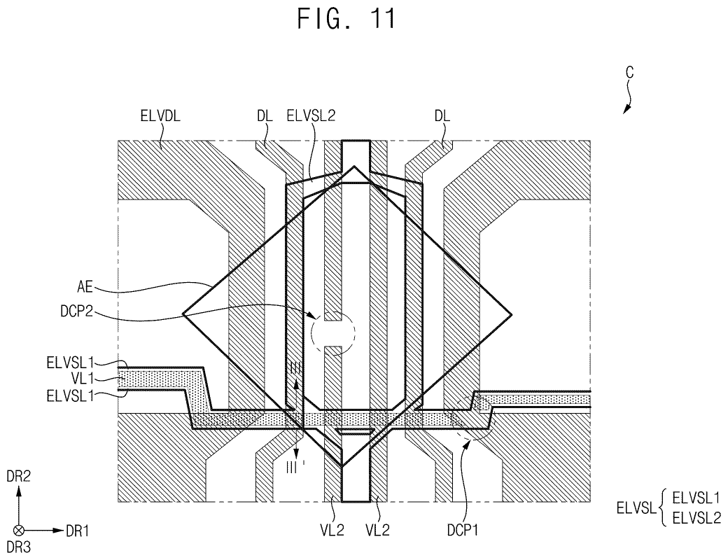

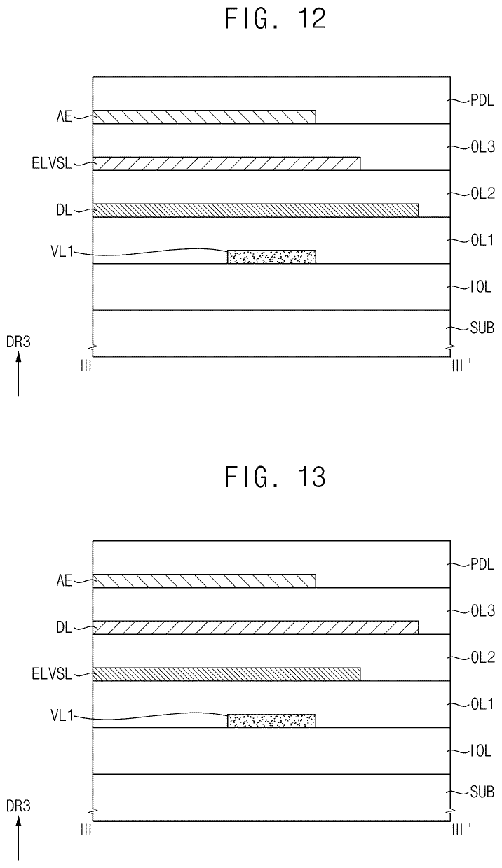

FIG. 11 is a plan view showing an embodiment of area C of FIG. 1.

Referring to FIG. 11, as described herein, the display area DA may include the driving voltage line ELVDL, the data line DL, the first voltage line VL1, the second voltage line VL2, and the common voltage line EVLSL. The common voltage line EVLSL may include the first common voltage line EVLS1 and the second common voltage line EVLS2.

The driving voltage line ELVDL, the data line DL, and the second voltage line VL2 may be disposed in the same layer and may include the same material.

In an embodiment, the second voltage line VL2 may be disposed between adjacent data lines DL in the plan view. For example, two second voltage lines VL2 may be disposed between two data lines DL in the plan view.

The anode electrode AE may be disposed on the driving voltage line ELVDL, the data line DL, the first voltage line VL1, the second voltage line VL2, and the common voltage line EVLSL. The anode electrode AE may at least partially overlap the driving voltage line ELVDL, the data line DL, the first voltage line VL1, the second voltage line VL2, and the common voltage line EVLSL in the plan view. In this case, the light emitting layer disposed on the anode electrode AE may include a light emitting material that may generate red light or blue light. Accordingly, a mura phenomenon, which may be caused by coupling between the data line DL and the anode electrode AE, may be improved. The mura phenomenon refers to, for example, evenness or consistency (or unevenness or inconsistency) in brightness, color, or texture across a display panel.

At least one of the first voltage lines VL1 may include a first disconnected portion DCP1, and at least one of the second voltage lines VL2 may include a second disconnected portion DCP2.

At least some of the driving voltage lines ELVDL may extend in the second direction DR2 to cover (or shield) the first disconnected portion DCP1 of the first voltage line VL1. In addition, in an embodiment, some of the first common voltage lines ELVSL1 may overlap the first voltage line VL1 in the plan view and may extend in the first direction DR1 to cover (or shield) the first disconnected portion DCP1 of the first voltage line VL1. Accordingly, the first disconnected portion DCP1 may not be visible.

At least some of the anode electrodes AE may cover (or shield) the second disconnected portion DCP2 of the second voltage line VL2. Accordingly, the second disconnected portion DCP2 may not be visible.

In an embodiment, at least some of the second common voltage lines ELVSL2 may extend in the second direction DR2 to cover (or shield) a portion of the data line DL overlapping the anode electrode AE. Accordingly, a mura phenomenon, which may be caused by coupling between the data line DL and the anode electrode AE, may be further improved.

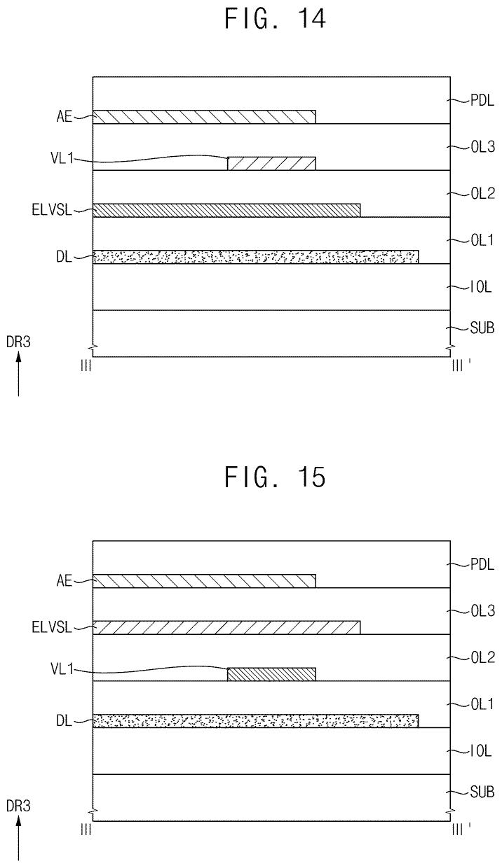

FIG. 12, FIG. 13, FIG. 14, and FIG. 15 are cross-sectional views showing embodiments of cross-sections taken along line III-III′ of FIG. 11. In FIGS. 12 to 15, components may be illustrated having different cross-hatching according to different material layers as illustrated in FIG. 3 and described below.

Referring to FIG. 11 and FIG. 12, in an embodiment, the first voltage line VL1 may be disposed in the same layer as the first source electrode SE1 and the first drain electrode DE1 of FIG. 3. The first voltage line VL1, the first source electrode SE1, and the first drain electrode DE1 may include the same material. The first voltage line VL1, the first source electrode SE1, and the first drain electrode DE1 may be formed through the same process. The data line DL and the second voltage line VL2 may be disposed in the same layer as the first connection electrode CE1 of FIG. 3. The data line DL and the second voltage line VL2 may include the same material as the first connection electrode CE1 of FIG. 3, and may be formed through the same process as the first connection electrode CE1 of FIG. 3. In addition, the common voltage line ELVSL may be disposed in the same layer as the second connection electrode CE2 of FIG. 3, may include the same material as the second connection electrode CE2 of FIG. 3, and may be formed through the same process as the second connection electrode CE2 of FIG. 3.

Referring to FIG. 11 and FIG. 13, in another embodiment, the first voltage line VL1 may be disposed in the same layer as the first source electrode SE1 and the first drain electrode DE1 of FIG. 3, may include the same material as the first source electrode SE1 and the first drain electrode DE1 of FIG. 3, and may be formed through the same process as the first source electrode SE1 and the first drain electrode DE1 of FIG. 3. The common voltage line ELVSL may be disposed in the same layer as the first connection electrode CE1 of FIG. 3, may include the same material as the first connection electrode CE1 of FIG. 3, and may be formed through the same process as the first connection electrode CE1 of FIG. 3. In addition, the data line DL and the second voltage line VL2 may be disposed in the same layer as the second connection electrode CE2 of FIG. 3, may include the same material as the second connection electrode CE2 of FIG. 3, and may be formed through the same process as the second connection electrode CE2 of FIG. 3.

Referring to FIG. 11 and FIG. 14, in another embodiment, the data line DL and the second voltage line VL2 may be dispose in the same layer as the first source electrode SE1 and the first drain electrode DE1 of FIG. 3, may include the same material as the first source electrode SE1 and the first drain electrode DE1 of FIG. 3, and may be formed through the same process as the first source electrode SE1 and the first drain electrode DE1 of FIG. 3. The common voltage line ELVSL may be disposed in the same layer as the first connection electrode CE1 of FIG. 3, may include the same material as the first connection electrode CE1 of FIG. 3, and may be formed through the same process as the first connection electrode CE1 of FIG. 3. In addition, the first voltage line VL1 may be disposed in the same layer as the second connection electrode CE2 of FIG. 3, may include the same material as the second connection electrode CE2 of FIG. 3, and may be formed through the same process as the second connection electrode CE2 of FIG. 3.

Referring to FIG. 11 and FIG. 15, in another embodiment, the data line DL and the second voltage line VL2 may be disposed in the same layer as the first source electrode SE1 and the first drain electrode DE1 of FIG. 3, may include the same material as the first source electrode SE1 and the first drain electrode DE1 of FIG. 3, and may be formed through the same process as the first source electrode SE1 and the first drain electrode DE1 of FIG. 3. The first voltage line VL1 may be disposed in the same layer as the first connection electrode CE1 of FIG. 3, may include the same material as the first connection electrode CE1 of FIG. 3, and may be formed through the same process as the first connection electrode CE1 of FIG. 3. In addition, the common voltage line ELVSL may be disposed in the same layer as the second connection electrode CE2 of FIG. 3, may include the same material as the second connection electrode CE2 of FIG. 3, and may be formed through the same process as the second connection electrode CE2 of FIG. 3.

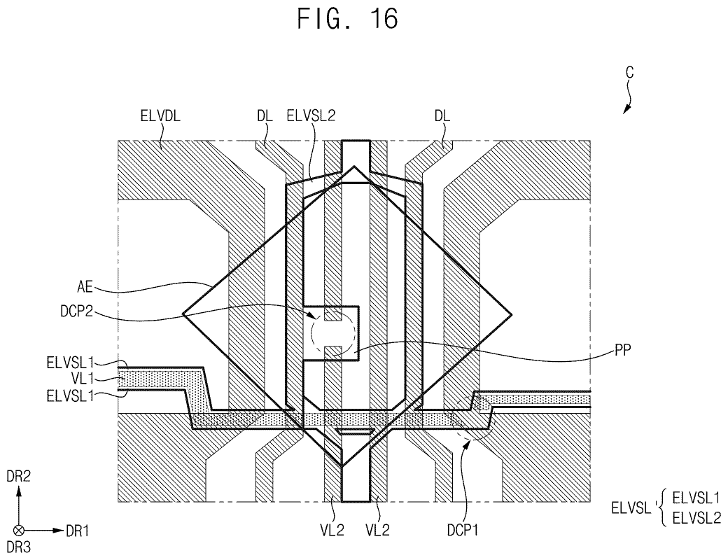

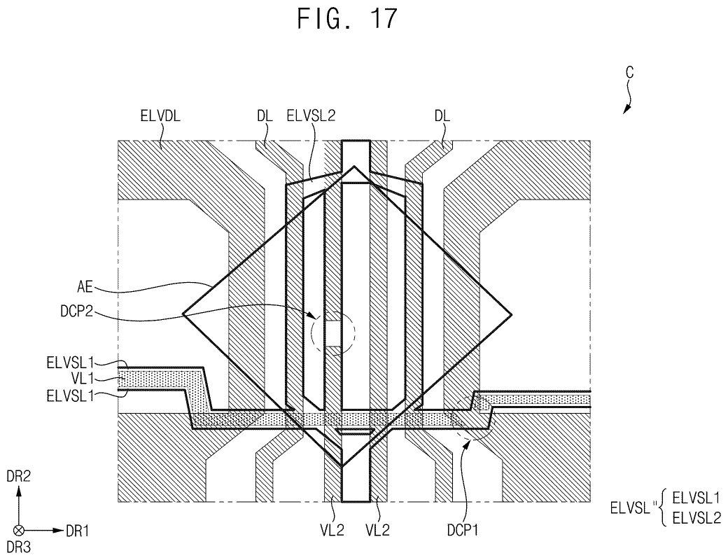

FIG. 16 is a plan view showing an embodiment of area C of FIG. 1. FIG. 17 is a plan view showing an embodiment of area C of FIG. 1.

Hereinafter, content overlapping with the content described with reference to FIG. 11 may be omitted or simplified.

Referring to FIG. 16 and FIG. 17, as described herein, some of the anode electrodes AE may cover (or shield) the second disconnected portion DCP2 of the second voltage line VL2. In addition, in an embodiment, common voltage lines ELVSL′ and ELVSL″ may cover (or shield) the second disconnected portion DCP2 of the second voltage line VL2. Specifically, the second common voltage line ELVSL2 of the common voltage lines ELVSL′ and ELVSL″ may cover (or shield) the second disconnected portion DCP2. Accordingly, the second disconnected portion DCP2 may not be visible.

For example, as shown in FIG. 16, the second common voltage line ELVSL2 of the common voltage line ELVSL′ may include a protrusion PP protruding in the first direction DR1 and covering (or shielding) the second disconnected portion DCP2.

In another example, as shown in FIG. 17, the second common voltage line ELVSL2 of the common voltage line ELVSL″ may be divided into a first pattern covering a portion of the data line DL overlapping the anode electrode AE, a second pattern overlapping the second voltage line VL2 and covering (or shielding) the second disconnected portion DCP2, and a third pattern covering a portion of the data line DL overlapping the anode electrode AE and spaced apart from the first pattern with the second pattern therebetween. Each of the first, second, and third patterns may extend in the second direction DR2.

Referring again to FIGS. 1 to 17, the display device DD according to embodiments of the present disclosure may include the common voltage supply line CVSL disposed in the peripheral area NDA, that may provide the common voltage ELVSS, and including the first metal line ML1, the second metal line ML2, the third metal line ML3, and the connection pattern CNP stacked sequentially, the transmission line SL disposed in the peripheral area NDA, including a same material as the third metal line ML3, and connected to the common voltage supply line CVSL through the connection pattern CNP, and the common voltage line ELVSL disposed in the display area DA, formed integrally with the transmission line SL, and having a mesh structure throughout the display area DA. Accordingly, a voltage drop (IR drop) of the common voltage ELVSS may be minimized or reduced. In this case, a power consumption of the display device DD may be improved.

In addition, the common voltage line ELVSL includes the first common voltage line ELVSL1 extending in the first direction DR1 and the second common voltage line ELVSL2 extending in the second direction DR2, and the second common voltage line ELVSL2 may cover (or shield) at least a portion of the data line DL overlapping the anode electrode AE. In addition, the first common voltage line ELVSL1 may cover (or shield) the first disconnected portion DCP1 of the first voltage line VL1, and the second common voltage line ELVSL2 may cover (or shield) the second disconnected portion DCP2 of the second voltage line VL2. Accordingly, coupling between the data line DL and the anode electrode AE may be inhibited or prevented, and the first and second disconnected portions DCP1 and DCP2 may not be visible.

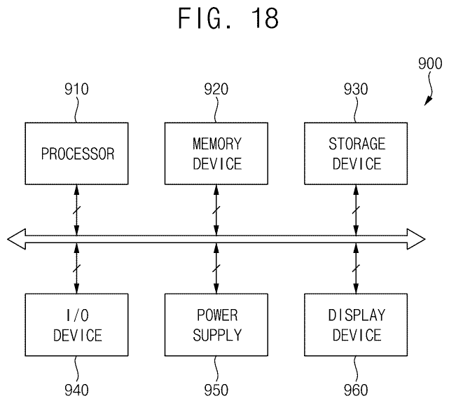

FIG. 18 is a block diagram illustrating an electronic device according to an embodiment of the present disclosure.

Referring to FIG. 18, in an embodiment, an electronic device 900 may include a processor 910, a memory device 920, a storage device 930, an input/output device 940, a power supply 950, and a display device 960. In this case, the display device 960 may correspond to the display device DD described with reference to FIGS. 1 to 17. The electronic device 900 may further include several ports capable of communicating with a video card, a sound card, a memory card, a USB device, and the like.

In an embodiment, the electronic device 900 may be implemented as a television. In another embodiment, the electronic device 900 may be implemented as a smart phone. However, the electronic device 900 is not limited thereto, and for example, the electronic device 900 may be implemented as a mobile phone, a video phone, a smart pad, a smart watch, a tablet PC, a vehicle navigation device, a computer monitor, a laptop computer, a head mounted display (HMD), and the like.

The processor 910 may perform certain calculations or tasks. The processor 910 may control the display device 960. In an embodiment, the processor 910 may be a microprocessor, a central processing unit (CPU), an application processor (AP), and/or the like. The processor 910 may be connected to other components through an address bus, a control bus, a data bus, and the like. The processor 910 may also be connected to an expansion bus, such as a peripheral component interconnect (PCI) bus.

The memory device 920 may store data necessary for the operation of the electronic device 900. For example, the memory device 920 may include an erasable programmable read-only memory (EPROM) device, an electrically erasable programmable read-only memory (EEPROM) device, a flash memory device, a phase change random access memory (PRAM) device, a resistance random access memory (RRAM) device, a nano floating GEe memory (NFGM) device, a polymer random access memory (PoRAM) device, a magnetic random access memory (MRAM) device, a non-volatile memory device such as a ferroelectric random access memory (FRAM) device and/or a volatile memory device such as a dynamic random access memory (DRAM) device, a static random access memory (SRAM) device, and a mobile DRAM device, and the like.

The storage device 930 may include a solid state drive (SSD), a hard disk drive (HDD), a CD-ROM, and the like.

The input/output device 940 may include input means such as a keyboard, keypad, touch pad, touch screen, mouse, and the like and output means such as a speaker, a printer, and the like.

The power supply 950 may supply power necessary for the operation of the electronic device 900. The display device 960 may be connected to other components through buses or other communication links. In an embodiment, the display device 960 may be included in the input/output device 940.

The present disclosure can be applied to various display devices. For example, the present disclosure is applicable to various display devices such as display devices for vehicles, ships and aircraft, portable communication devices, display devices for exhibition or information transmission, or medical display devices.

The foregoing is illustrative of embodiments and is not to be construed as limiting thereof. Although embodiments have been described, those skilled in the art will readily appreciate that many modifications are possible without materially departing from the novel teachings and advantages of the present inventive concept. Accordingly, all such modifications are intended to be included within the scope of the present inventive concept as defined in the claims. Therefore, it is to be understood that the foregoing is illustrative of various embodiments and is not to be construed as limited to the specific embodiments disclosed, and that modifications to disclosed embodiments, as well as other embodiments, are intended to be included within the scope of the appended claims.

What is claimed is:

1. A display device comprising:
a substrate including a display area and a peripheral area disposed at a side of the display area;
a light emitting element disposed in the display area and including an anode electrode, a light emitting layer disposed on the anode electrode, and a cathode electrode disposed on the light emitting layer and extending from the display area to the peripheral area;
a common voltage supply line disposed in the peripheral area, electrically connected to the cathode electrode, and including:
a first metal line;
a second metal line disposed on the first metal line and contacting the first metal line;
a third metal line disposed on the second metal line and contacting the second metal line; and
a connection pattern including a same material as the anode electrode and contacting the third metal line and the cathode electrode; and
a transmission line disposed in the peripheral area, including a same material as the third metal line, and connected to the common voltage supply line through the connection pattern.

2. The display device of claim 1, further comprising:
a gate driver disposed in the peripheral area and including at least on driver transistor; and
a control signal line disposed in the peripheral area, electrically connected to the gate driver, the third metal line, and the transmission line,
wherein the connection pattern overlaps the control signal line in a plan view and is spaced apart from the control signal line.

3. The display device of claim 1, further comprising:
a first organic insulating layer disposed on the substrate and extending from the display area to the peripheral area to cover an end portion of the first metal line;
a second organic insulating layer disposed on the second organic insulating layer and extending from the display area to the peripheral area to cover an end portion of the second metal line; and
a third organic insulating layer disposed on the second organic insulating layer and extending from the display area to the peripheral area to cover an end portion of the third metal line.

4. The display device of claim 3, wherein an opening is defined in the third organic insulating layer to expose at least a portion of the transmission line, and
the connection pattern contacts the transmission line through the opening.

5. The display device of claim 4, wherein the transmission line is directly connected to an end portion of the common voltage supply line adjacent to a pad area of the peripheral area.

6. The display device of claim 3, wherein a plurality of through holes exposing at least a portion of the third organic insulating layer are defined in the connection pattern.

7. The display device of claim 3, wherein the cathode electrode extends from the display area to a position overlapping an end portion of the third organic insulating layer contacting the third metal line.

8. The display device of claim 3, further comprising:
a first voltage line disposed in the display area and extending in a first direction; and
a second voltage line disposed in the display area, disposed on a different one of the first organic insulating layer, the second organic insulating layer, or the third organic insulating layer from the first voltage line, and extending in a second direction crossing the first direction.

9. The display device of claim 8, wherein the transmission line is connected to the first voltage line through a first contact hole penetrating the first organic insulating layer and the second organic insulating layer, and
the transmission line is connected to the second voltage line through a second contact hole penetrating the first organic insulating layer.

10. The display device of claim 8, wherein in an area adjacent to an edge portion of the display area adjacent to a pad area of the peripheral area,
the first voltage line is divided into a first part connected to the second voltage line, a second part spaced apart from the first part in a direction opposite to the first direction and connected to a first transmission line portion of the transmission line, and a third part spaced apart from the first part in the first direction and connected to a second transmission line portion of the transmission line.

11. The display device of claim 8, further comprising:
a common voltage line disposed in the display area, electrically connected to the common voltage supply line, and having a mesh structure.

12. The display device of claim 11, wherein the common voltage line is directly connected to an end portion of the common voltage supply line adjacent to a pad area of the peripheral area.

13. The display device of claim 11, further comprising:
a data line extending in the second direction,
wherein the anode electrode at least partially overlaps the data line in a plan view, and
the common voltage line includes:
a first common voltage line overlapping the first voltage line in a plan view and extending in the first direction; and
a second common voltage line covering a portion of the data line overlapping the anode electrode and extending in the second direction.

14. The display device of claim 13, wherein the first common voltage line covers at least one disconnected portion of at least one of the first voltage line or the second voltage line.

15. A display device comprising:
a substrate including a display area and a peripheral area surrounding at least a portion of the display area;
a light emitting element disposed in the display area and including an anode electrode, a light emitting layer disposed on the anode electrode, and a cathode electrode disposed on the light emitting layer and extending from the display area to the peripheral area;
a common voltage supply line comprising a plurality of metal layers sequentially stacked and disposed in the peripheral area, and contacting the cathode electrode;
a first voltage line disposed in the display area and extending in a first direction;
a second voltage line disposed in the display area, disposed on a different layer from the first voltage line, extending in a second direction crossing the first direction; and
a common voltage line disposed in the display area, electrically connected to the common voltage supply line, and having a mesh structure.

16. The display device of claim 15, further comprising:
a first organic insulating layer disposed on the substrate and extending from the display area to the peripheral area;
a second organic insulating layer disposed on the second organic insulating layer and extending from the display area to the peripheral area; and
a third organic insulating layer disposed on the second organic insulating layer and extending from the display area to the peripheral area,
wherein the common voltage line is disposed between the second organic insulating layer and the third organic insulating layer.

17. The display device of claim 15, wherein the common voltage line is directly connected to an end portion of the common voltage supply line adjacent to a pad area of the peripheral area.

18. The display device of claim 15, further comprising:
a data line extending in the second direction,
wherein the anode electrode at least partially overlaps the data line in a plan view, and
the common voltage line includes:
a first common voltage line covering a disconnected portion of the first voltage line in a plan view and extending in the first direction; and
a second common voltage line covering a portion of the data line overlapping the anode electrode and extending in the second direction.

19. The display device of claim 15, comprising a mesh structure in a portion of the display area comprising the first voltage line and the second voltage line.

20. The display device of claim 15, wherein at least a portion of the common voltage line covers a portion of the first voltage line and at least a portion of the anode electrode covers a portion of the second voltage line.

21. An electronic device comprising:
a display device; and
a processor which controls the display device,
wherein display device includes:
a substrate including a display area and a peripheral area disposed at a side of the display area;
a light emitting element disposed in the display area and including an anode electrode, a light emitting layer disposed on the anode electrode, and a cathode electrode disposed on the light emitting layer and extending from the display area to the peripheral area;
a common voltage supply line disposed in the peripheral area, electrically connected to the cathode electrode, and including:
a first metal line;
a second metal line disposed on the first metal line and contacting the first metal line;
a third metal line disposed on the second metal line and contacting the second metal line; and
a connection pattern including a same material as the anode electrode and contacting the third metal line and the cathode electrode; and
a transmission line disposed in the peripheral area, including a same material as the third metal line, and connected to the common voltage supply line through the connection pattern.
